(19) United States
(12) Patent Application Publication
(10) Pub. No.: US 2023/0031737 A1
(43) Pub. Date: Feb. 2, 2023

(54) LIGHT SENSING DEVICE

(71) Applicant: Egis Technology Inc., Hsinchu City (TW)

(72) Inventor: Chin-An Hsieh, Hsinchu City (TW)

(73) Assignee: Egis Technology Inc., Hsinchu City (TW)

(21) Appl. No.: 17/572,660

(22) Filed: Jan. 11, 2022

Related U.S. Application Data
(60) Provisional application No. 63/227,325, filed on Jul. 29, 2021.

(30) Foreign Application Priority Data
Nov. 11, 2021 (CN) 202111334634.7

(51) Int. Cl. H01L 31/107; G01J 1/42; H01L 27/144

(52) U.S. Cl. CPC H01L 31/107; G01J 1/42; H01L 27/1446

(57) ABSTRACT

A light sensing device including a first conductivity type buried layer, a second conductivity type well, and a first conductivity type well is provided. The second conductivity type well is on the first conductivity type buried layer. The first conductivity type well is on the second conductivity type well and surrounded by the second conductivity type well.

### CROSS-REFERENCE TO RELATED APPLICATION

This application claims the priority benefit of U.S. provisional application Ser. No. 63/227,325, filed on Jul. 29, 2021 and China application no. 202111334634.7, filed on Nov. 11, 2021. The entirety of each of the above-mentioned patent applications is hereby incorporated by reference herein and made a part of this specification.

### BACKGROUND

### Technical Field

The invention relates to an electronic device, and particularly relates to a light sensing device.

### Description of Related Art

When a PN diode in a single-photon avalanche diode operates above a breakdown voltage, before an initial carrier appears and causes subsequent breakdown, the PN diode has no avalanche current therein and is in an OFF state, and after the PN diode receives a photon and generates the initial carrier to cause the breakdown, the PN diode generates an avalanche current and enters an ON state. At this time, an external circuit (e.g., a cut-off circuit) detects breakdown and quickly reduces a bias voltage of the PN diode to be below the breakdown voltage to prevent the PN diode from being burned by an excessive current, and waits until the breakdown is finished (the avalanche current returns to zero) before increasing the bias voltage to be above the breakdown voltage again, and waits for a next occurrence of breakdown. The above-mentioned time of reducing and re-increasing the bias voltage is not applicable to photon detection, and is generally referred to as a dead time, which may be as long as tens of nanoseconds (ns) to several microseconds (μs). Therefore, under a circumstances where the area is fixed, how to increase a quantity of photodiodes to effectively improve the efficiency of photon collection is one of issues to be addressed by R&D personnel.

### SUMMARY

The invention provides a light sensing device, which helps to improve efficiency of photon collection.

According to an embodiment of the invention, a light sensing device includes a first conductivity type buried layer, a second conductivity type well, and a first conductivity type well. The second conductivity type well is on the first conductivity type buried layer. The first conductivity type well is on the second conductivity type well and surrounded by the second conductivity type well.

In an embodiment of the invention, the second conductivity type well contacts a top surface of the first conductivity type buried layer and contacts a bottom surface and a side surface of the first conductivity type well.

In an embodiment of the invention, the light sensing device further includes a second conductivity type high-voltage well and a first conductivity type high-voltage well. The second conductivity type high-voltage well surrounds the second conductivity type well. The first conductivity type high-voltage well is on the first conductivity type buried layer and surrounds the second conductivity type high-voltage well.

In an embodiment of the invention, the second conductivity type high-voltage well contacts a side surface of the second conductivity type well and is separated from the first conductivity type buried layer.

In an embodiment of the invention, the first conductivity type high-voltage well contacts a top surface of the first conductivity type buried layer and is separated from the second conductivity type high-voltage well.

In an embodiment of the invention, the light sensing device further includes a first heavily doped region, a second heavily doped region, and a third heavily doped region. The first heavily doped region is on the first conductivity type well and is surrounded by the first conductivity type well, where the first heavily doped region has a first conductivity type. The second heavily doped region is on the second conductivity type high-voltage well and is surrounded by the second conductivity type high-voltage well, where the second heavily doped region has a second conductivity type. The third heavily doped region is on the first conductivity type high-voltage well and is surrounded by the first conductivity type high-voltage well, where the third heavily doped region has the first conductivity type, and the third heavily doped region is electrically insulated from the first heavily doped region.

In an embodiment of the invention, the first conductivity type is N-type, the second conductivity type is P-type, and the second heavily doped region is connected to a negative bias voltage.

In an embodiment of the invention, the first conductivity type is P-type, the second conductivity type is N-type, and the second heavily doped region is connected to a positive bias voltage.

In an embodiment of the invention, one sensing unit is framed by the first conductivity type high-voltage well. The sensing unit includes a plurality of pixels divided by the second conductivity type high-voltage well. Each pixel includes one first conductivity type well and one second conductivity type well.

In an embodiment of the invention, the light sensing device further includes a second conductivity type substrate, where the first conductivity type buried layer, the second conductivity type well, and the first conductivity type well are in the second conductivity type substrate.

According to an embodiment of the invention, a light sensing device includes a first PN junction and a second PN junction. The second PN junction is overlapped with the first PN junction in a thickness direction of the light sensing device, where an area of the second PN junction is larger than an area of the first PN junction.

In an embodiment of the invention, the light sensing device includes a plurality of first PN junctions.

In an embodiment of the invention, the light sensing device further includes a first conductivity type buried layer, a plurality of second conductivity type wells, and a plurality of first conductivity type wells. The plurality of second conductivity type wells are arranged on the first conductivity type buried layer, where the second PN junction is at a junction between the plurality of second conductivity type wells and the first conductivity type buried layer. The plurality of first conductivity type wells are respectively on the plurality of second conductivity type wells and each first conductivity type well is surrounded by a corresponding one of the second conductivity type wells, where the first PN junction is at a junction between each first conductivity type well and the corresponding one of the second conductivity type wells.

In an embodiment of the invention, the light sensing device further includes a second conductivity type high-voltage well and a first conductivity type high-voltage well. The second conductivity type high-voltage well surrounds the plurality of second conductivity type wells, and adjacent two of the second conductivity type wells are separated by the second conductivity type high-voltage well. The first conductivity type high-voltage well is on the first conductivity type buried layer and surrounds the second conductivity type high-voltage well.

In an embodiment of the invention, the second conductivity type high-voltage well contacts a side surface of the second conductivity type well and is separated from the first conductivity type buried layer.

In an embodiment of the invention, the first conductivity type high-voltage well contacts the first conductivity type buried layer and is separated from the second conductivity type high-voltage well.

Based on the above description, in the embodiments of the invention, under a circumstance where the area is fixed, the number of photodiodes may be increased through vertical PN junction stacking, thus helping to improve the efficiency of photon collection.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic partial top view of a light sensing device according to an embodiment of the invention.

FIG. 2 is a schematic cross-sectional view taken along section line I-I′ in FIG. 1.

### DESCRIPTION OF THE EMBODIMENTS

Directional terminology mentioned in the following embodiments, such as “top,” “bottom,” “front,” “back,” “left,” “right,” etc., is used with reference to the orientation of the FIG(s) being described and are not intended to limit the disclosure.

In the FIGs, each of the drawings depicts typical features of methods, structures, and/or materials used in the particular exemplary embodiments. However, these drawings are not to be interpreted as limiting or limiting the scope or property covered by these exemplary embodiments. For example, for clarity, relative thickness and position of each film layer, region and/or structure may be reduced or enlarged.

In the following embodiments, the same or similar components are denoted by the same or similar referential numbers, and descriptions of the same technical contents are omitted. Moreover, the features in the different exemplary embodiments may be combined with each other in case of no confliction, and the simple equivalent changes and modifications made in accordance with the scope of the specification or the claims are still within the scope of the patent.

“First”, “second”, etc. mentioned in the specification and the claims are merely used to name discrete components and should not be regarded as limiting the upper or lower bound of the number of the components, nor is it used to define a manufacturing order or setting order of the components. In addition, one element/film layer arranged on (or above) another element/film layer may cover a situation that the element/film layer is directly arranged on (or above) the other element/film layer, and the two elements/film layers direct contact with each other, and a situation that the element/film layer is indirectly arranged on (or above) the other element/film layer, and there are one or more elements/film layers between the two elements/film layers.

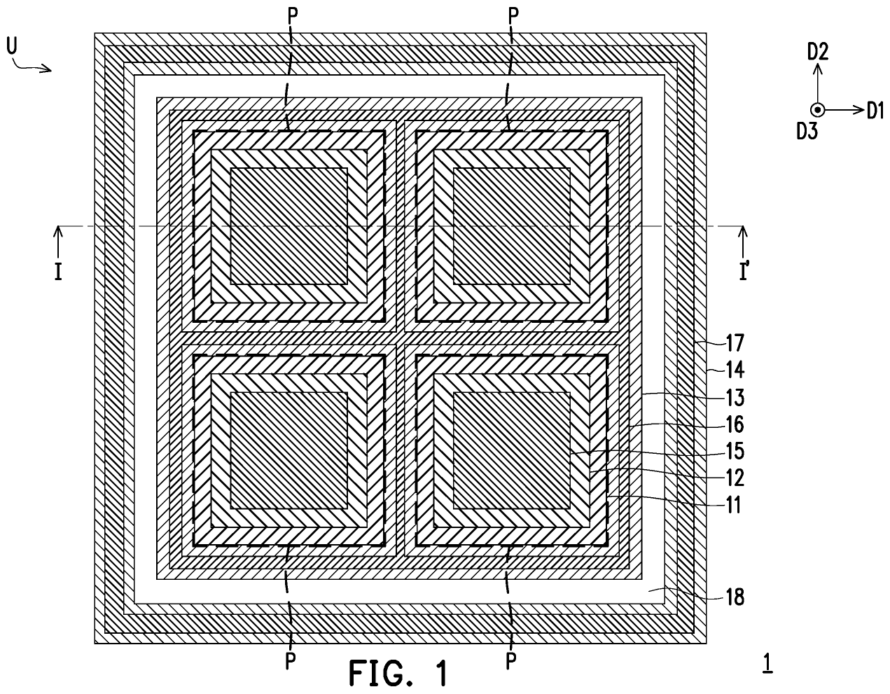

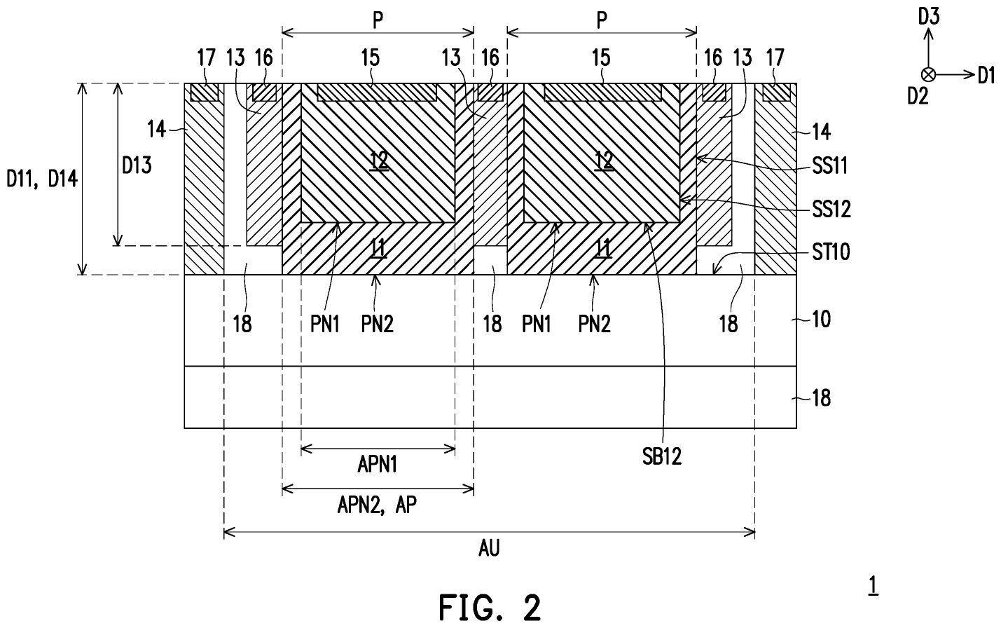

FIG. 1 is a schematic partial top view of a light sensing device 1 according to an embodiment of the invention. FIG. 2 is a schematic cross-sectional view taken along section line I-I′ in FIG. 1.

Referring to FIG. 1 and FIG. 2, the light sensing device 1 is, for example, a SPAD (single-photon avalanche diode) sensor, and the light sensing device 1 may be applied to depth sensing, such as time of flight (TOF) or light detection and ranging (LiDAR), but the invention is not limited thereto.

The light sensing device 1 may include a first conductivity type buried layer 10, a second conductivity type well 11, and a first conductivity type well 12. The second conductivity type well 11 is on the first conductivity type buried layer 10. The first conductivity type well 12 is on the second conductivity type well 11 and is surrounded by the second conductivity type well 11.

In some embodiments, the second conductivity type well 11 contacts a top surface ST10 of the first conductivity type buried layer 10 and contacts a bottom surface SB12 and a side surface SS12 of the first conductivity type well 12. In other words, there is no other film layer or region between the first conductivity type buried layer 10 and the second conductivity type well 11, and there is no other film layer or region between the second conductivity type well 11 and the first conductivity type well 12.

In some embodiments, the light sensing device 1 may further include a second conductivity type high-voltage well 13 and a first conductivity type high-voltage well 14. The second conductivity type high-voltage well 13 surrounds the second conductivity type well 11. The first conductivity type high-voltage well 14 is on the first conductivity type buried layer 10 and surrounds the second conductivity type high-voltage well 13.

In some embodiments, the second conductivity type high-voltage well 13 contacts a side surface SS11 of the second conductivity type well 11 and is separated from the first conductivity type buried layer 10. For example, a depth D13 of the second conductivity type high-voltage well 13 may be smaller than a depth D11 of the second conductivity type well 11, and a part (for example, a lower part) of the side surface SS11 (the lower part) of the second conductivity type well 11 is not wrapped by the second conductivity type high-voltage well 13.

In some embodiments, the first conductivity type high-voltage well 14 contacts the top surface ST10 of the first conductivity type buried layer 10, and a depth D14 of the first conductivity type high-voltage well 14 may be equal to the depth D1l of the second conductivity type well 11. In addition, the first conductivity type high-voltage well 14 is separated from the second conductivity type high-voltage well 13.

In some embodiments, the light sensing device 1 may further include a first heavily doped region 15, a second heavily doped region 16, and a third heavily doped region 17. The first heavily doped region 15 is on the first conductivity type well 12 and is surrounded by the first conductivity type well 12, where the first heavily doped region 15 has a first conductivity type, and a doping concentration of the first heavily doped region 15 may be higher than a doping concentration of the first conductivity type well 12. The second heavily doped region 16 is on the second conductivity type high-voltage well 13 and is surrounded by the second conductivity type high-voltage well 13, where the second heavily doped region 16 has a second conductivity type, and a doping concentration of the second heavily doped region 16 may be higher than a doping concentration of the second conductivity type high-voltage well 13. The third heavily doped region 17 is on the first conductivity type high-voltage well 14 and is surrounded by the first conductivity type high-voltage well 14, where the third heavily doped region 17 has the first conductivity type, and a doping concentration of the third heavily doped region 17 may be higher than a doping concentration of the first conductivity type high-voltage well 14, and the third heavily doped region 17 is electrically insulated from the first heavily doped region 15.

In some embodiments, the first conductivity type is N-type, the second conductivity type is P-type, and the second heavily doped region 16 is connected to a negative bias voltage. However, in some other embodiments, the first conductivity type is P-type, the second conductivity type is N-type, and the second heavily doped region 16 is connected to a positive bias voltage.

In some embodiments, one sensing unit U is framed by the first conductivity type high-voltage well 14, and the sensing unit U may also be referred to as a SPAD cell. The sensing unit U includes a plurality of pixels P divided by the second conductivity type high-voltage well 13. Each pixel P includes one first conductivity type well 12 and one second conductivity type well 11. The one first conductivity type well 12 and the one second conductivity type well 11 are stacked in a direction D3 to form a photodiode.

FIG. 1 schematically illustrates a sensing unit U in the light sensing device 1. However, it should be understood that the light sensing device 1 may include one or a plurality of sensing units U. The plurality of sensing units U may be arranged in an array in a direction D1 and a direction D2, but the invention is not limited thereto. The direction D1 and the direction D2 are intersected with each other and are both perpendicular to the thickness direction (for example, the direction D3) of the light sensing device 1. In some embodiments, the direction D1 and the direction D2 are perpendicular to each other, but the invention is not limited thereto.

FIG. 1 schematically illustrates that the sensing unit U includes four pixels P. However, it should be understood that the sensing unit U may include more or fewer pixels P. The plurality of pixels P may be arranged in an array in the direction D1 and the direction D2, but the invention is not limited thereto. A quantity, an arrangement method or a top view shape of the pixels P in each sensing unit U may be changed according to actual requirements, and is not limited to those shown in FIG. 1. For example, although not shown, the top view shape of the pixels P may also be a circle or other polygons.

In some embodiments, the light sensing device 1 may further include a second conductivity type substrate 18, where the first conductivity type buried layer 10, the second conductivity type well 11, the first conductivity type well 12, the second conductivity type high-voltage well 13, the first conductivity type high-voltage well 14, the first heavily doped region 15, the second heavily doped region 16 and the third heavily doped region 17 are in the second conductivity type substrate 18. For example, the first conductivity type buried layer 10, the second conductivity type well 11, the first conductivity type well 12, and the second conductivity type high-voltage well 13, the first conductivity type high-voltage well 14, the first heavily doped region 15, the second heavily doped region 16 and the third heavily doped region 17 may be formed in the second conductivity type substrate 18 through an ion implantation process. Where, dopants of the P-type semiconductor may include trivalent elements, such as boron, aluminum, gallium, and indium, but the invention is not limited thereto. Dopants of the N-type semiconductor may include pentavalent elements, such as phosphorus, arsenic, and antimony, but the invention is not limited thereto.

Taking the second conductivity type substrate 18 of a P-type substrate as an example, an N-type buried layer (e.g., the first conductivity type buried layer 10), an N-type high-voltage well (e.g., the first conductivity type high-voltage well 14), N-type heavily doped regions (e.g., the third heavily doped region 17 and the first heavily doped region 15), an N-type deep well (e.g., the first conductivity type well 12), a P-type deep well (e.g., the second conductivity type well 11), a P-type high-voltage well (e.g., the second conductivity type high-voltage well 13), and a P-type heavily doped region (e.g., the second heavily doped region 16) may be formed in the P-type substrate through multiple ion implantation processes. There is an undoped P-type substrate (the second conductivity type substrate 18) between the second conductivity type high-voltage well 13, the first conductivity type high-voltage well 14 and the first conductivity type buried layer 10, i.e., the second conductivity type high-voltage well 13 is separated from the first conductivity type high-voltage well 14 through the second conductivity type substrate 18, and the second conductivity type high-voltage well 13 is separated from the first conductivity type buried layer 10 through the second conductivity type substrate 18. In addition, there is an undoped P-type substrate (the second conductivity type substrate 18) between the second conductivity type high-voltage well 13, the second conductivity type well 11, and the first conductivity type buried layer 10, i.e., the second conductivity type high-voltage well 13 is separated from the first conductivity type buried layer 10 through the second conductivity type substrate 18, and two of the adjacent second conductivity type wells 11 are separated from each other through the second conductivity type substrate 18.

The light sensing device 1 may include a first PN junction PN1 and a second PN junction PN2. The second PN junction PN2 is overlapped with the first PN junction PN1 in the thickness direction (for example, the direction D3) of the light sensing device 1, where an area APN2 of the second PN junction PN2 is larger than an area APN1 of the first PN junction PN1.

In detail, the second PN junction PN2 is at a junction between the plurality of second conductivity type wells 11 and the first conductivity type buried layer 10, and the first PN junction PN1 is at a junction between each first conductivity type well 12 and the corresponding one second conductivity type well 11.

In the light sensing device 1, an avalanche current generated between the second conductivity type well 11 and the corresponding first conductivity type well 12 may be output through the corresponding first heavily doped region 15, while an avalanche current generated between the plurality of second conductivity type wells 11 and the first conductivity type buried layer 10 may be output through the third heavily doped region 17. An additional PN junction (e.g., the second PN junction PN2) is formed by contacting the plurality of second conductivity type wells 11 with the first conductivity type buried layer 10, and the avalanche current generated between the plurality of second conductivity type wells 11 and the first conductivity type buried layer 10 is output through the first conductivity type high-voltage well 14 and the third heavily doped region 17, which is equivalent to adding a light-receiving photodiode under a circumstance where the area is fixed, and an area of the photodiode is larger than an area AP of each pixel P and is similar to an area AU of the sensing unit U or similar to a sum of the areas AP of the plurality of pixels P in the sensing unit U.

By increasing a quantity of the photodiodes, a timing difference of the dead time of different photodiodes may be used to collect photons incident at different time, thereby helping to improve the efficiency of photon collection and mitigating the problem of poor efficiency of photon collection caused by the dead time.

In other embodiments, although not shown, the light sensing device 1 may also include an interconnection structure, a CMOS chip, a reading circuit or other circuits, which is not limited by the invention.

In summary, in the embodiments of the invention, under a circumstance where the area is fixed, the number of photodiodes may be increased through vertical PN junction stacking, thus helping to improve the efficiency of photon collection.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A light sensing device, comprising:
a first conductivity type buried layer;
a second conductivity type well, being on the first conductivity type buried layer; and
a first conductivity type well, being on the second conductivity type well and surrounded by the second conductivity type well.

2. The light sensing device as claimed in claim 1, wherein the second conductivity type well contacts a top surface of the first conductivity type buried layer and contacts a bottom surface and a side surface of the first conductivity type well.

3. The light sensing device as claimed in claim 1, further comprising:
a second conductivity type high-voltage well, surrounding the second conductivity type well; and
a first conductivity type high-voltage well, being on the first conductivity type buried layer and surrounding the second conductivity type high-voltage well.

4. The light sensing device as claimed in claim 3, wherein the second conductivity type high-voltage well contacts a side surface of the second conductivity type well and is separated from the first conductivity type buried layer.

5. The light sensing device as claimed in claim 3, wherein the first conductivity type high-voltage well contacts a top surface of the first conductivity type buried layer and is separated from the second conductivity type high-voltage well.

6. The light sensing device as claimed in claim 3, further comprising:
a first heavily doped region, being on the first conductivity type well and surrounded by the first conductivity type well, wherein the first heavily doped region has a first conductivity type;
a second heavily doped region, being on the second conductivity type high-voltage well and surrounded by the second conductivity type high-voltage well, wherein the second heavily doped region has a second conductivity type; and
a third heavily doped region, being on the first conductivity type high-voltage well and surrounded by the first conductivity type high-voltage well, wherein the third heavily doped region has the first conductivity type, and the third heavily doped region is electrically insulated from the first heavily doped region.

7. The light sensing device as claimed in claim 6, wherein the first conductivity type is N-type, the second conductivity type is P-type, and the second heavily doped region is connected to a negative bias voltage.

8. The light sensing device as claimed in claim 6, wherein the first conductivity type is P-type, the second conductivity type is N-type, and the second heavily doped region is connected to a positive bias voltage.

9. The light sensing device as claimed in claim 3, wherein one sensing unit is framed by the first conductivity type high-voltage well, the sensing unit comprises a plurality of pixels divided by the second conductivity type high-voltage well, and each of the pixels comprises one first conductivity type well and one second conductivity type well.

10. The light sensing device as claimed in claim 1, further comprising:
a second conductivity type substrate, wherein the first conductivity type buried layer, the second conductivity type well, and the first conductivity type well are in the second conductivity type substrate.

11. A light sensing device, comprising:
a first PN junction; and
a second PN junction, overlapped with the first PN junction in a thickness direction of the light sensing device, wherein an area of the second PN junction is larger than an area of the first PN junction.

12. The light sensing device as claimed in claim 11, wherein the light sensing device comprises a plurality of first PN junctions.

13. The light sensing device as claimed in claim 11, further comprising:
a first conductivity type buried layer,
a plurality of second conductivity type wells, arranged on the first conductivity type buried layer, wherein the second PN junction is at a junction between the plurality of second conductivity type wells and the first conductivity type buried layer; and
a plurality of first conductivity type wells, being respectively on the plurality of second conductivity type wells and each surrounded by a corresponding one of the second conductivity type wells, wherein the first PN junction is at a junction between each first conductivity type well and the corresponding one of the second conductivity type wells.

14. The light sensing device as claimed in claim 13, further comprising:
a second conductivity type high-voltage well, surrounding the plurality of second conductivity type wells, wherein adjacent two of the second conductivity type wells are separated by the second conductivity type high-voltage well; and
a first conductivity type high-voltage well, being on the first conductivity type buried layer and surrounding the second conductivity type high-voltage well.

15. The light sensing device as claimed in claim 14, wherein the second conductivity type high-voltage well contacts a side surface of the second conductivity type well and is separated from the first conductivity type buried layer.

16. The light sensing device as claimed in claim 14, wherein the first conductivity type high-voltage well contacts the first conductivity type buried layer and is separated from the second conductivity type high-voltage well.
